(19) United States
(12) Patent Application Publication
(10) Pub. No.: US 2006/0278889 A1
(43) Pub. Date: Dec. 14, 2006

(54) Power rectifier and manufacturing method thereof

(75) Inventors: Chieh-Hung Tsai, Keelung City (TW); Ching-Chiu Tseng, Keelung City (TW); Hung-Lung Cheng, Taipei City (TW)

Correspondence Address: BIRCH STEWART KOLASCH & BIRCH, PO BOX 747, FALLS CHURCH, VA, 22040-0747, US

(73) Assignee: LITE-ON SEMICONDUCTOR CORP.

(21) Appl. No.: 11/148,388

(22) Filed: Jun. 9, 2005

(51) Int. Cl. H01L 29/74

(52) U.S. Cl. 257/119

(57) ABSTRACT

A power rectifier and its manufacturing method are proposed in the present invention. A cylinder-shaped PN junction is formed during the manufacturing process of the power rectifier. Via the effect of the curved surface of the cylinder-shaped PN junction, a breakdown path under a reverse bias is provided so as to control the breakdown voltage. In this way, the defects of the power diode won't affect the forming of the depletion region and the voltage snap-down problem is eliminated.

### BACKGROUND OF THE INVENTION

1. Field of the Invention

The present invention is related to a power rectifier and its manufacturing method, and more particularly, to a power rectifier and a manufacturing method that employs a cylinder-shaped PN junction to provide a breakdown path under a reverse bias.

2. Description of Related Art

Power rectifiers are common electronic components and important elements for electronic circuits. A good power rectifier should have a low forward voltage, a high switching speed and a high breakdown voltage. Specifically, when the power diode is used as a power supply, it needs a higher breakdown voltage to prevent any abnormal operation of the power rectifier due to the occurrence of impulsive waves sent from the external electric source that may make the circuit of the power supply malfunction. Thus, how to design and manufacture a power diode having a high breakdown voltage has become an important issue.

Reference is made to FIG. 1, which is a schematic diagram of a conventional power rectifier. As shown in the figure, a lightly doped N-type region 12 is first formed on a heavily doped N+ substrate 10 via an epitaxial process. Next, a heavily doped P+ region 14 is formed on the lightly doped N-type region 12 via a high-temperature diffusion process. Lastly, a metal material is provided on the heavily doped P+ region 14 and the heavily doped N+ substrate 10 to form an anode and a cathode (not shown) via an evaporation deposition process or other deposition processes. Thus, a power diode with a PN junction is formed.

In the foresaid structure of the power diode, since the lightly doped N-type region 12 is first formed on the heavily doped N+ substrate 10 via the epitaxial process, lattice defects, such as lattice dislocation, are usually formed in the junction region. These lattice defects influence the forming of the depletion region of the PN junction of the power rectifier under a reverse bias. Hence, the depletion region of the PN junction cannot withstand the high electric field and a voltage snap-down problem occurs when a reverse bias is provided onto the power rectifier.

U.S. Pat. No. 6,114,193 was proposed to prevent the voltage snap-down problem. Reference is made to FIG. 2, which is a schematic diagram of a power rectifier provided in U.S. Pat. No. 6,114,193. The power rectifier includes a first conductive substrate 28, a second conductive epitaxy layer 24, a third conductive doped layer 22 and an isolation layer 26 located between the first conductive substrate 28 and the second conductive epitaxy layer 24. The isolation layer 26 is used to prevent the forming of the depletion region of the PN junction of the power diode from being affected by the lattice defects under a reverse bias. Thus, the voltage snap-down problem is eliminated. However, this diode structure is formed with two epitaxy layers so it has higher cost. Furthermore, since the impurity concentrations of these two epitaxy layers are different, they are not stable during the high-temperature diffusion process. Thus, the breakdown voltage cannot be controlled easily and is unstable in mass production.

Accordingly, as discussed above, the prior art still has some drawbacks that could be improved upon. The present invention aims to resolve the drawbacks of the prior art.

### SUMMARY OF THE INVENTION

An objective of the present invention is to provide a power rectifier and its manufacturing method. The present invention performs two impurity diffusion processes with different depths on a semiconductor substrate to form a cylinder-shaped area at an edge of a PN junction of the power rectifier. Via the effect of the curved surface of the cylinder-shaped PN junction, the present invention provides a breakdown path under a reverse bias to control the breakdown voltage. In this way, the present invention can prevent the voltage snap-down problem caused by the power rectifier cannot withstand the high electric field due to the lattice defects of the substrate.

For achieving the objective above, the present invention provides a power rectifier, including a first semiconductor layer having a first conductive type; a second semiconductor layer adjacent to the first semiconductor layer and having the first conductive type, the second semiconductor layer having an impurity concentration lower than that of the first semiconductor layer; and a third semiconductor layer having a cylinder-shaped junction adjacent to the second semiconductor layer and having a second conductive type.

The present invention also provides a method for manufacturing the power rectifier, including providing a semiconductor substrate having a first conductive type; forming an oxide layer on the semiconductor substrate; forming a window on the oxide layer via a photolithographic process and an oxide-etching process; doping the semiconductor substrate with impurities via the window, the impurities being diffused into the semiconductor substrate via a high temperature diffusion process to form a deeper diffusion region to provide a cylinder-shaped junction in the semiconductor substrate along an edge of the window; and removing the oxide layer and further doping the semiconductor substrate with the impurities via the high temperature diffusion process to form a shallower diffusion region in the semiconductor substrate. Therein, the shallower diffusion region is combined with the deeper diffusion region to the third semiconductor layer, which has deeper and shallow regions and a cylinder-shaped junction as its edge.

When a reverse bias is provided onto the power rectifier, the cylinder-shaped PN junction has a higher electric field intensity and thus has a lower breakdown voltage. Hence, the value of the breakdown voltage is determined according to the properties of this portion. Since the cylinder-shaped PN junction will break down first, the forming of the depletion region will not be affected by the lattice defects. Thus, the voltage snap-down problem is eliminated.

Numerous additional features, benefits and details of the present invention are described in the detailed description, which follows.

### BRIEF DESCRIPTION OF THE DRAWINGS

The foregoing aspects and many of the attendant advantages of this invention will be more readily appreciated as the same becomes better understood by reference to the following detailed description, when taken in conjunction with the accompanying drawings, wherein:

FIG. 1 is a schematic diagram of a conventional power rectifier;

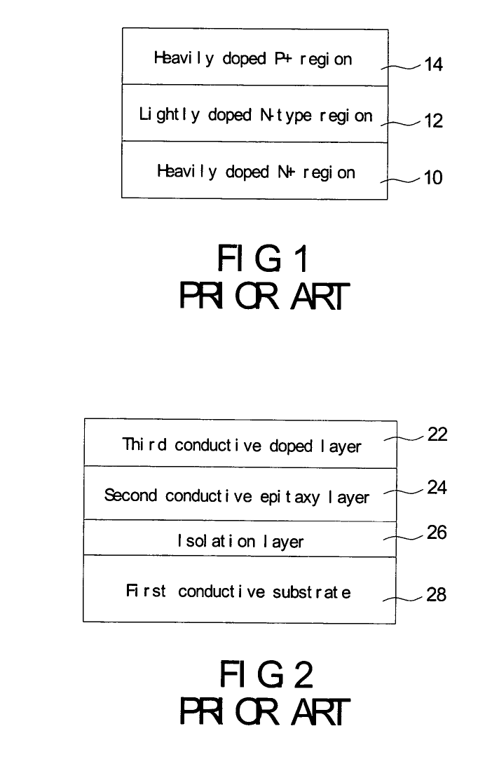

FIG. 2 is a schematic diagram of another conventional power rectifier;

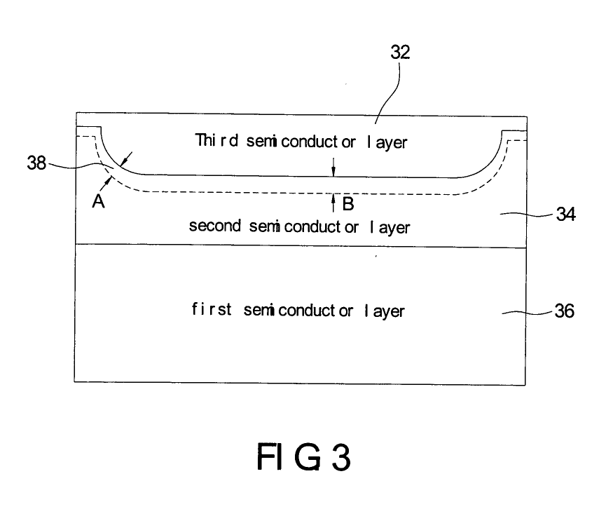

FIG. 3 is a schematic diagram of a power rectifier in accordance with the present invention;

FIGS. 4a-f are schematic diagrams showing a manufacturing process in accordance with the present invention; and

FIG. 5 is a flow chart of the manufacturing process in accordance with the present invention.

### DETAILED DESCRIPTION OF PREFERRED EMBODIMENTS

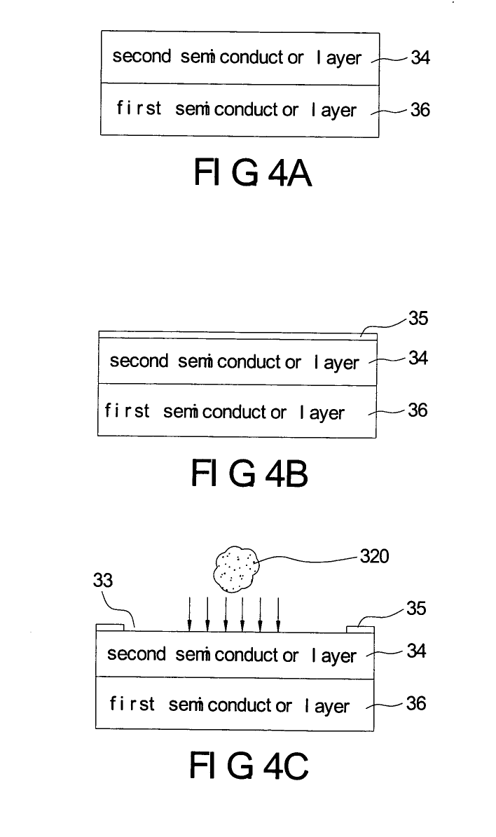

Reference is made to FIG. 3, which is a schematic diagram of a power rectifier in accordance with the present invention. The power rectifier includes a first semiconductor layer 36, a second semiconductor layer 34 and a third semiconductor layer 32. The first semiconductor layer 36 is a silicon substrate formed via a CZ/FZ/NTD process and has a first conductive type. The second semiconductor layer 34 is an epitaxy layer, which is formed on the first semiconductor layer 36 via an epitaxial process, and also has the first conductive type. The impurity concentration of the first conductive type is lower than that of the first semiconductor layer. The third semiconductor layer 32 is a diffused layer and has a second conductive type, which is formed via two impurity diffusion processes with different depths to provide a PN junction of the power rectifier having a cylinder-shaped junction surrounding the PN junction.

In the foresaid description, if the first conductive type is an N-type conductive type, the second conductive type is a P-type conductive type. On the contrary, if the first conductive type is a P-type conductive type, the second conductive type is an N-type conductive type.

Furthermore, when a reverse bias is provided onto the power diode, a depletion region 38 is formed along the PN junction located between the second semiconductor layer 34 and the third semiconductor layer 32. The width of the depletion region 38 located at the cylinder-shaped area A is relatively smaller than that located at the plane area B. Thus, when a reverse bias is provided onto the power diode, the electric field intensity at the cylinder-shaped area A is greater than that at the plane area B. Hence, the cylinder-shaped area A has a lower breakdown voltage. When the reverse bias voltage increases, the cylinder-shaped area A will breaks down first but the plane area B doesn't break down. In this way, the present invention prevents the forming of the depletion region of the PN junction being affected by the lattice defects under a reverse bias. Thus, the voltage snap-down problem is eliminated.

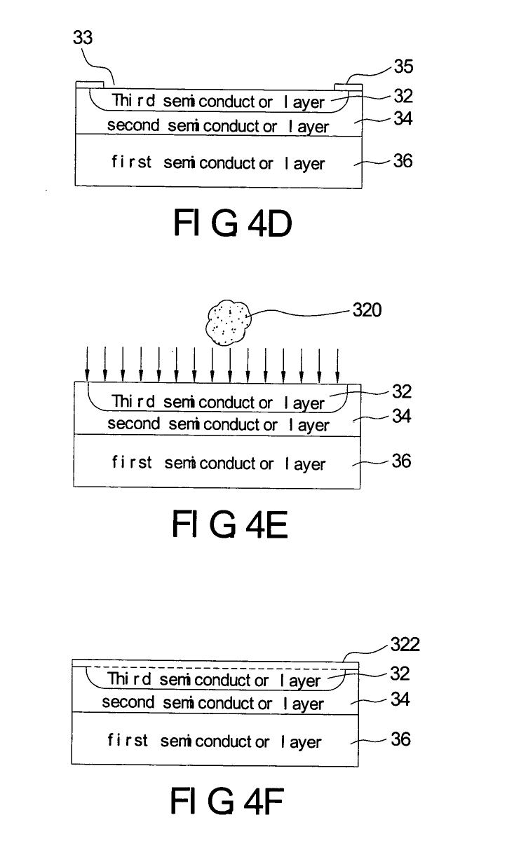

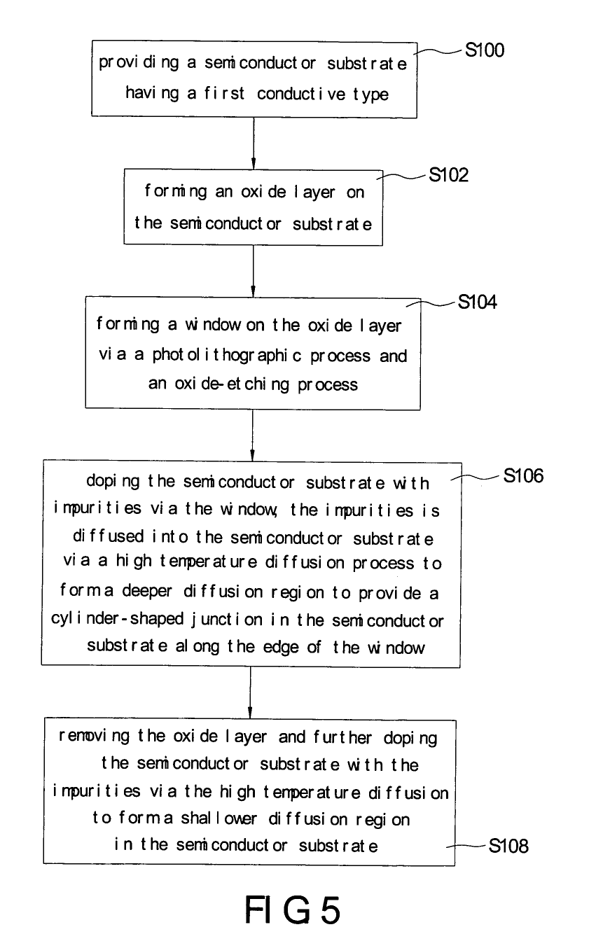

Reference is made to FIGS. 4a-f, which are schematic diagrams showing a manufacturing process in accordance with the present invention. Reference is also made to FIG. 5, which is a flow chart of the manufacturing process in accordance with the present invention. The manufacturing process of present invention has the following steps: providing a semiconductor substrate having a first conductive type (S100), wherein the semiconductor substrate includes a silicon substrate 36 and an epitaxy layer 34 and the impurity concentration of the substrate 36 having the first conductive type is greater than that of the epitaxy layer 34; then, providing an oxide layer 35 on the semiconductor substrate via an oxidation process (S102); subsequently, forming a window 33 on the oxide layer 35 via a photolithographic process and an oxide-etching process (S104); furthermore, doping the semiconductor substrate with impurities 320 via the window 33, wherein the impurities 320 are diffused into the semiconductor substrate via a high temperature diffusion process to form a deeper diffusion region 32 which provides a cylinder-shaped junction in the semiconductor substrate along the edge of the window 33 (S106); finally, removing the oxide layer 35 and further doping the semiconductor substrate with the impurities 320 via high-temperature diffusion to form a shallower diffusion region 322 (S108). In the foresaid description, the deeper diffusion layer 32 and the shallower diffusion region 322 are combined to form a semiconductor diffusion layer.

In the foresaid description, the impurities are diffused into the epitaxy layer 34 of the semiconductor substrate via a high temperature diffusion process to form a PN junction. The edge of the PN junction forms a cylinder-shaped PN junction along the edge of the window33. Furthermore, if the impurities with the first conductive type used in the semiconductor substrate are N-type impurities, the impurities 320 are P-type impurities. On the contrary, if the impurities with the first conductive type used in the semiconductor substrate are P-type impurities, the impurities 320 are N-type impurities.

To sum up, the present invention uses two impurity diffusion processes with different depths to provide the semiconductor diffusion layer 32. The edge of the PN junction located between the semiconductor diffusion layer 32 and the epitaxy layer 34 forms a cylinder-shaped area. Via the effect of the curved surface of the cylinder-shaped PN junction, when a reverse bias is provided onto the power diode, the cylinder-shaped PN junction has a higher electric field intensity. Thus, this region has a lower breakdown voltage. Hence, the value of the breakdown voltage is determined according to the properties of the cylinder-shaped PN junction. When a reverse bias is provided, the cylinder-shaped PN junction will first break down but the planar PN junction won't break down. In this way, the present invention prevents the forming of the depletion region from being affected by the lattice defects located between the first semiconductor layer 36 and the second semiconductor 34. Thus, the voltage snap-down problem is eliminated.

Meanwhile, the present invention uses a single epitaxy layer only. Thus, its cost is lower than that of the prior art that uses two epitaxy layers. Furthermore, the high-temperature diffusion process is easily controlled and stable for the single epitaxy layer. Hence, the drawback of the prior art that the rectifier structure with two epitaxy layers is unstable and cannot be controlled easily during the high-temperature diffusion process is overcome.

Although the present invention has been described with reference to the preferred embodiment thereof, it will be understood that the invention is not limited to the details thereof. Various substitutions and modifications have been suggested in the foregoing description, and others will occur to those of ordinary skill in the art. Therefore, all such substitutions and modifications are embraced within the scope of the invention as defined in the appended claims.

What is claimed is:

1. A power rectifier, comprising:
a first semiconductor layer having a first conductive type;
a second semiconductor layer adjacent to the first semiconductor layer and having the first conductive type, the second semiconductor layer having an impurity concentration lower than that of the first semiconductor layer; and
a third semiconductor layer having a cylinder-shaped junction adjacent to the second semiconductor layer and having a second conductive type.

2. The power rectifier as claimed in claim 1, wherein the first semiconductor layer is a silicon substrate.

3. The power rectifier as claimed in claim 1, wherein the second semiconductor layer is an epitaxy layer.

4. The power rectifier as claimed in claim 1, wherein the third semiconductor layer is a semiconductor diffusion layer.

5. The power rectifier as claimed in claim 1, wherein the first conductive type is an N-type conductive type and the second conductive type is a P-type conductive type.

6. The power rectifier as claimed in claim 1, wherein the first conductive type is a P-type conductive type and the second conductive type is an N-type conductive type.

7. The power rectifier as claimed in claim 1, wherein a PN junction is formed between the second semiconductor layer and the third semiconductor layer.

8. A method for manufacturing a power rectifier, comprising:
providing a semiconductor substrate having a first conductive type;
forming an oxide layer on the semiconductor substrate;
forming a window on the oxide layer via a photolithographic process and an oxide-etching process;
doping the semiconductor substrate with impurities via the window, the impurities being diffused into the semiconductor substrate via a high temperature diffusion process to form a deeper diffusion region to provide a cylinder-shaped junction in the semiconductor substrate along the edge of the window; and
removing the oxide layer and further doping the semiconductor substrate with the impurities via the high temperature diffusion process to form a shallower diffusion region in the semiconductor substrate.

9. The method as claimed in claim 8, wherein the semiconductor substrate comprises a silicon substrate and an epitaxy layer and the silicon substrate having the first conductive type has an impurity concentration greater than that of the epitaxy layer.

10. The method as claimed in claim 8, wherein the cylinder-shaped junction is a PN junction.

11. The method as claimed in claim 8, wherein the first conductive type is an N-type conductive type and the impurities are P-type impurities.

12. The method as claimed in claim 8, wherein the first conductive type is a P-type conductive type and the impurities are N-type impurities.
